(19) United States
(12) Patent Application Publication
(10) Pub. No.: US 2025/0374483 A1
(43) Pub. Date: Dec. 4, 2025

(54) IMMERSION COOLING SYSTEM

(71) Applicant: AEWIN TECHNOLOGIES CO., LTD., New Taipei City (TW)

(72) Inventors: Cheng-En LIU, New Taipei City (TW); Chien-Fu WANG, New Taipei City (TW); Chen-Ping HSU, New Taipei City (TW); Nien-Chu CHANG, New Taipei City (TW)

(21) Appl. No.: 19/016,867

(22) Filed: Jan. 10, 2025

(30) Foreign Application Priority Data
Jun. 3, 2024 (TW) 113120524

(51) Int. Cl. H05K 7/20

(52) U.S. Cl. CPC H05K 7/2029

(57) ABSTRACT

An immersion cooling system is provided and includes a box body, a plurality of tank bodies and at least one suction unit. The box body has a first accommodating space. The plurality of tank bodies are arranged in the first accommodating space, and each of the plurality of tank bodies is defined with a vapor space and a liquid storage space. The at least one suction unit is disposed on at least one inner sidewall of each of the tank bodies between the vapor space and the liquid storage space.

### CROSS-REFERENCE TO RELATED APPLICATIONS

This application claims priority to Taiwan Application Serial No. 113120524, filed on Jun. 3, 2024. The entirety of the above-mentioned patent application is hereby incorporated by reference herein and made a part of this specification.

### BACKGROUND

### 1. Technical Field

The present disclosure relates to a cooling system, and more particularly, to an immersion cooling system provided with a suction unit to increase a contact area between a liquefied heat dissipation medium and a vapor space.

### 2. Description of Related Art

The two-phase immersion cooling method utilizes the phase conversion between the gas state and the liquid state of the water-cooling liquid to take away heat. Specifically, the water-cooling liquid in the sealed tank absorbs the heat energy generated by the heating element and gasifies, then the gasified water-cooling liquid condenses on a condenser after contacting the condenser, and droplets of the water-cooling liquid condensed on the condenser fall back into the water-cooling liquid by gravity, thereby achieving the heat dissipation effect of the heating element via this circulation.

However, the existing two-phase immersion cooling method still has problems such as slow flow of the hot and cold layers in the water-cooling liquid, small contact area between the liquid layer and the vapor layer, and uneven distribution of the hot and cold layers in the water-cooling liquid and the like, thereby resulting in poor heat exchange efficiency. In addition, the space for components having low heating power still needs to be filled with a large amount of water-cooling liquid, thereby resulting in high costs.

### SUMMARY

The present disclosure provides an immersion cooling system, which comprises: a box body having a first accommodating space; a plurality of tank bodies arranged in the first accommodating space, wherein each of the plurality of tank bodies contains a heat dissipation medium, and defines a vapor space and a liquid storage space connected to the vapor space, wherein a liquefied heat dissipation medium is accommodated in the liquid storage space, and a gasified heat dissipation medium is accommodated in the vapor space; and at least one suction unit disposed on at least one inner sidewall of each of the tank bodies between the vapor space and the liquid storage space, and configured for attracting the liquefied heat dissipation medium in the liquid storage space and guiding the liquefied heat dissipation medium to the vapor space, so as to increase a contact area between the liquefied heat dissipation medium and the vapor space.

In the aforementioned immersion cooling system, the suction unit is polyvinyl alcohol foam.

In the aforementioned immersion cooling system, a porosity of the polyvinyl alcohol foam is between 89% and 95%.

In the aforementioned immersion cooling system, a pore size of the polyvinyl alcohol foam is between 380 μm and 1100 μm.

In the aforementioned immersion cooling system, a proportion of the suction unit located in the vapor space and the liquid storage space is 50% each.

In the aforementioned immersion cooling system, the liquefied heat dissipation medium in the liquid storage space defines a plurality of stratified sections along a direction of gravity, and temperatures of the heat dissipation medium in the plurality of stratified sections are different from each other.

In the aforementioned immersion cooling system, the suction unit is further disposed on at least one inner sidewall of each of the tank bodies between each of the plurality of stratified sections.

In the aforementioned immersion cooling system, each of the plurality of tank bodies is provided with a heating unit, and the heating unit is immersed in the liquefied heat dissipation medium in the liquid storage space.

In the aforementioned immersion cooling system, the suction unit is further disposed on the heating unit.

In the aforementioned immersion cooling system, the vapor space and the liquid storage space are arranged up and down along a direction of gravity, and the vapor space and the liquid storage space are not connected to the first accommodating space.

In the aforementioned immersion cooling system, the plurality of tank bodies are arranged side by side in the first accommodating space in a direction perpendicular to a direction of gravity.

In the aforementioned immersion cooling system, the box body further has a second accommodating space and a water collecting tank connected to the second accommodating space, and the second accommodating space and the water collecting tank are arranged up and down along a direction of gravity.

In the aforementioned immersion cooling system, the present disclosure further comprises a condensing unit disposed in the second accommodating space, wherein the heat dissipation medium gasifies after absorbing thermal energy, and the gasified heat dissipation medium is introduced into the second accommodating space, so that the gasified heat dissipation medium is condensed and liquefied through heat exchange by the condensing unit, and the liquefied heat dissipation medium is introduced into the water collecting tank and then returned to each of the tank bodies.

To sum up, by arranging a suction unit in the immersion cooling system of the present disclosure, the liquefied heat dissipation medium in the liquid storage space can be guided to the vapor space. Compared with the prior art where only the liquid surface area of the liquefied heat dissipation medium contacts the vapor space, the present disclosure also has an additional liquefied heat dissipation medium located in the suction unit of the vapor space that can contact the vapor space. Therefore, the present disclosure effectively increases the contact area between the liquefied heat dissipation medium and the vapor space, thereby improving the heat exchange efficiency and heat exchange speed. Furthermore, the present disclosure can also have the effects of reducing the usage of heat dissipation medium, uniform temperature distribution of the heat dissipation medium, and no additional power consumption of the flow guiding mechanism.

### BRIEF DESCRIPTION OF THE DRAWINGS

FIG. 1 is a three-dimensional schematic view of an immersion cooling system according to one embodiment of the present disclosure.

FIG. 2 is a three-dimensional schematic view of the immersion cooling system according to another embodiment of the present disclosure.

FIG. 3 is a schematic cross-sectional view of a side of the immersion cooling system according to yet another embodiment of the present disclosure.

### DETAILED DESCRIPTION

The following describes the implementation of the present disclosure with examples. Those skilled in the art can easily understand other advantages and effects of the present disclosure from the contents disclosed in this specification, and can implement or apply the present disclosure via other different embodiments.

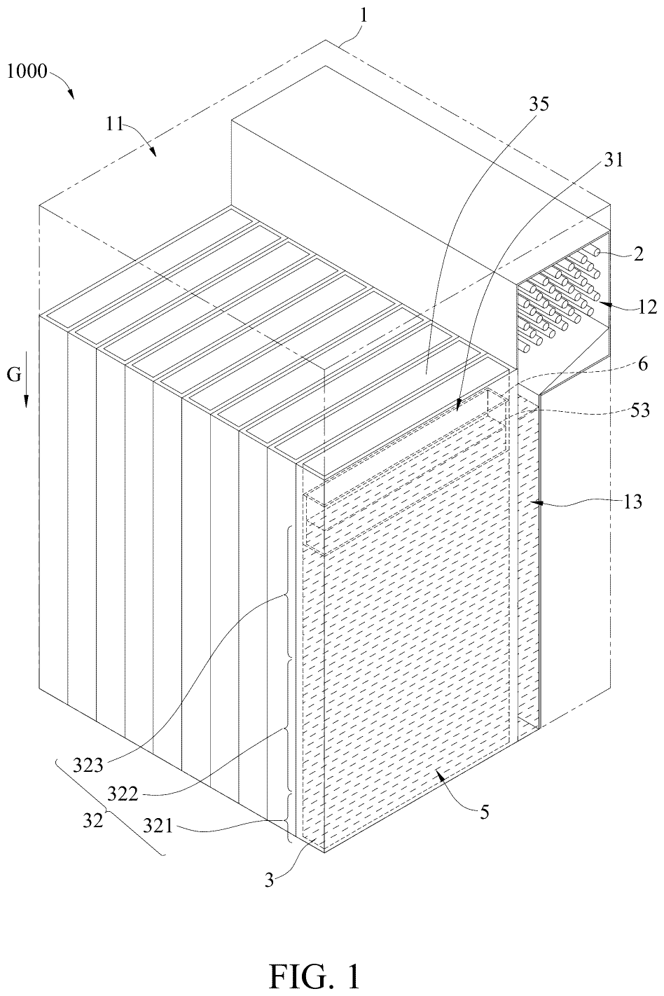

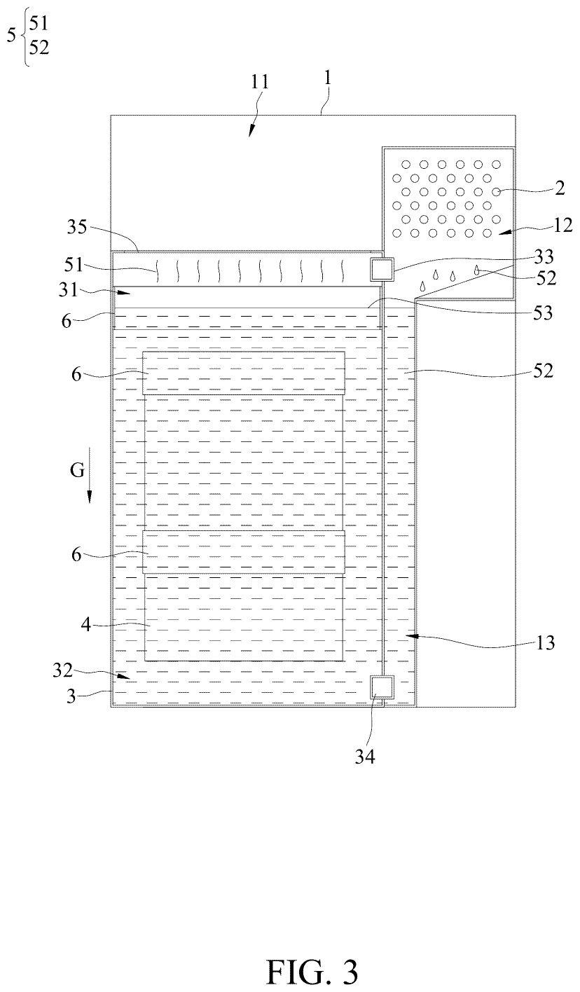

Please refer to FIG. 1 (a first valve unit 33, a second valve unit 34 and a heating unit 4 are omitted for clearer presentation) and FIG. 3, an immersion cooling system 1000 of the present disclosure includes a box body 1, a condensing unit 2, a plurality of tank bodies 3 and at least one suction unit 6. The structure of each element and the connection relationship between each other will be described in detail below, wherein some figures show the direction of gravity G.

The box body 1 can specifically be a two-phase immersed cooling positive high-pressure sealed tank, and the two-phase immersed cooling positive high-pressure sealed tank has a first accommodating space 11, a second accommodating space 12 and a water collecting tank 13 defined therein. The first accommodating space 11 and the second accommodating space 12 or the water collecting tank 13 can be separated from each other by partitions or the plurality of tank bodies 3, while the second accommodating space 12 is connected to the water collecting tank 13. In one embodiment, the second accommodating space 12 and the water collecting tank 13 are arranged up and down along the direction of gravity G, and the first accommodating space 11 is located on one side of the second accommodating space 12 and the water collecting tank 13.

The condensing unit 2 is arranged in the second accommodating space 12. In one embodiment, the condensing unit 2 may be a condenser, such as a U-shaped condenser, a straight condenser, or a serpentine condenser, wherein both ends of the condenser can be connected to a loop-shaped pipe, and a heat exchange device (such as a heat pipe), a water-cooling radiator (such as a fan), and a pump can be disposed on the loop-shaped pipe, and wherein the pump can drive the water-cooling liquid in the condenser and the loop-shaped pipe.

The plurality of tank bodies 3 are each roughly in the shape of a rectangular parallelepiped, and are arranged side by side in the first accommodating space 11 along a direction perpendicular to the direction of gravity G, thereby separating the first accommodating space 11 and the water collecting tank 13. In other embodiments, the first accommodating space 11 and the water collecting tank 13 can also be separated by a partition first. At this time, the partition needs to have openings for a first valve unit 33 and a second valve unit 34 to pass through, but the present disclosure is not limited to as such.

Each tank body 3 is independent and has a vapor space 31 and a liquid storage space 32 connected to the vapor space 31 defined therein. Two openings (not shown) can be opened on one side plate separating the first accommodating space 11 and the water collecting tank 13. The two openings are used to install the first valve unit 33 and the second valve unit 34 respectively (for example, FIG. 3). One opening is close to the top side of each tank body 3, and the other opening is close to the bottom side of each tank body 3, so that the first valve unit 33 and the second valve unit 34 are arranged up and down along the direction of gravity G, and the first valve unit 33 and the second valve unit 34 respectively correspond to the upper and lower sides of the water collecting tank 13.

The vapor space 31 and the liquid storage space 32 are arranged up and down along the direction of gravity G. The vapor space 31 is connected to the first valve unit 33 to accommodate a gasified heat dissipation medium 51. The liquid storage space 32 is connected to the second valve unit 34 and is used to accommodate a liquefied heat dissipation medium 52. As shown in FIG. 3, the liquid storage space 32 in each tank body 3 can be provided with a heating unit 4, and the heating unit 4 can be immersed in the liquefied heat dissipation medium 52. In one embodiment, the boundary between the vapor space 31 and the liquid storage space 32 can be determined by the liquefied heat dissipation medium 52. As long as the heating unit 4 can be completely immersed in the liquefied heat dissipation medium 52, a horizontal plane 53 of the liquefied heat dissipation medium 52 is the boundary, and the boundary is generally adjacent to but not in contact with the first valve unit 33.

In one embodiment, the first valve unit 33 is a one-way valve, which allows the vapor space 31 and the second accommodating space 12 to be connected to each other. The second valve unit 34 is a three-way valve, which allows the liquid storage space 32 and the water collecting tank 13 to be connected to each other, and can also be connected to a backup side tank. By controlling the second valve unit 34, the liquid storage space 32 and the water collecting tank 13 can be connected to each other, but not connected to the backup side tank, or the liquid storage space 32 and the backup side tank can be connected to each other, but not connected to the water collecting tank 13, so as to guide a heat dissipation medium 5 to a desired space.

In other embodiments, the second valve unit 34 can also be a one-way valve connected to the liquid storage space 32 and the water collecting tank 13, and the second valve unit 34 can be changed to be connected to the liquid storage space 32 and the backup side tank when needed, wherein a pump is used to guide the heat dissipation medium 5 from the liquid storage space 32 to the backup side tank.

In one embodiment, the heat dissipation medium 5 can be, for example, non-conductive water-cooling liquid, and the heating unit 4 can be, for example, a 2U server (a server that occupies two units of a standard server rack), wherein there are, for example, central processing units, graphics chips, other types of chips, or other heat sources inside the 2U server that generate heat, but the present disclosure is not limited to as such.

The top side of each tank body 3 may have a cover plate 35 adjacent to the first valve unit 33, wherein the cover plate 35 can be used to separate the vapor space 31 and the first accommodating space 11, and can be locked and sealed on the top side of each tank body 3, or can be detached from the top side of each tank body 3. When the cover plate 35 is closed on the top side of one of the tank bodies 3, the vapor space 31 and the liquid storage space 32 are not connected to the first accommodating space 11, and are not connected to the vapor spaces 31 and the liquid storage spaces 32 of other tank bodies 3.

The immersion cooling system 1000 of the present disclosure operates as follows. The liquefied heat dissipation medium 52 in the liquid storage space 32 gasifies after absorbing the heat energy generated by the heating unit 4, wherein the gasified heat dissipation medium 51 moves to the vapor space 31 and moves to the second accommodating space 12 via the first valve unit 33, and wherein, at this time, the condensing unit 2 allows the gasified heat dissipation medium 51 to perform heat exchange. After heat exchange between the water-cooling liquid in the condensing unit 2 and the gasified heat dissipation medium 51, the heated water-cooling liquid will flow along the loop-shaped pipe to the heat exchange device for cooling, and the pump can drive the cooled water-cooling liquid to return to the condensing unit 2 via the loop-shaped pipe for heat exchange in the next cycle. The gasified heat dissipation medium 51 is condensed and liquefied after heat exchange. The liquefied heat dissipation medium 52 drips from the condensing unit 2 and is concentrated in the water collecting tank 13. Thereafter, the liquefied heat dissipation medium 52 can be guided back to the liquid storage space 32 in the tank body 3 via the second valve unit 34 for the next heat dissipation cycle.

It can be seen from the above heat dissipation cycle that the heat dissipation medium 5 in the tank body 3 will have different temperatures at different locations. Because the liquefied heat dissipation medium 52 will flow upward after absorbing the heat energy generated by the heating unit 4, and the liquefied heat dissipation medium 52 will return to the bottom side of the tank body 3 after being cooled by the condensing unit 2, the liquefied heat dissipation medium 52 in the liquid storage space 32 will define a plurality of stratified sections 321, 322, and 323 along the direction of gravity G. The temperatures in the plurality of stratified sections 321, 322, and 323 are different from each other. For example, the temperature of the stratified section 321 is the coldest, the temperature of the stratified section 322 is the second (for example, between 3° C. and 13° C.), and the temperature of the stratified section 323 is the highest (for example, between 7° C. and 18° C.), and the like. The above numbers of the stratified sections 321, 322, and 323 are only examples, and the present disclosure is not limited to as such.

A suction unit 6 is disposed on at least one inner sidewall of the tank body 3 between the vapor space 31 and the liquid storage space 32 to attract the liquefied heat dissipation medium 52 in the liquid storage space 32, wherein the liquefied heat dissipation medium 52 is directed to the vapor space 31 to increase a contact area between the liquefied heat dissipation medium 52 and the vapor space 31.

In one embodiment, the suction unit 6 is polyvinyl alcohol (PVA) foam, wherein the porosity of the polyvinyl alcohol foam is between 89% and 95%, and the pore size (e.g., the pore diameter) of the polyvinyl alcohol foam is between 380 μm and 1100 μm, but the present disclosure is not limited to as such.

Polyvinyl alcohol foam has the ability to attract the heat dissipation medium 5 (or other liquids), and the ability to attract heat dissipation medium with a higher temperature is higher than the ability to attract heat dissipation medium with a lower temperature. As shown in Table 1 below, the dry polyethylene foam is put into liquids of different temperatures, and the suction height is measured after 24 hours. The results show that the smaller the pore size of polyvinyl alcohol foam, the higher the attraction ability, that is, the faster the attraction speed, and the attraction speed at high temperature is higher than the attraction speed at low temperature.

TABLE 1

| | | Suction height of | Suction height of |
|---|---|---|---|
| Porosity | Pore size | liquid at 20° C. | liquid at 80° C. |
| 95% | 590 μm | 90 mm | 100 mm |
| 84% | 1100 μm | 70 mm | 75 mm |
| 89% | 380 μm | 160 mm | 180 mm |

In one embodiment, the suction unit 6 is preferably made of polyvinyl alcohol (PVA) foam with a porosity of 89%, a pore size of 380 μm, and a thickness of 8 mm. The actual test of the attraction speed of polyvinyl alcohol foam of this specification shows that the attraction speed for heat dissipation medium 5 with a high temperature is indeed higher than the attraction speed for heat dissipation medium 5 with a low temperature (specifically, it is 20% or more faster), but the present disclosure is not limited to as such.

In one embodiment, the proportion of the suction unit 6 located in the vapor space 31 and the liquid storage space 32 is 50% each, but the present disclosure is not limited to as such. It can also be that the part of the suction unit 6 located in the vapor space 31 is larger than the part of the suction unit 6 located in the liquid storage space 32, for example, 60% to 40%, 70% to 30%, etc., and vice versa.

In one embodiment, the suction unit 6 is in the form of a rectangular plate and is adhered to at least one inner sidewall of the tank body 3. In other embodiments, a plurality of suction units 6 can be respectively adhered to the four connected inner sidewalls of the tank body 3, or a single suction unit 6 is arranged to surround the four connected inner sidewalls of the tank body 3, but the present disclosure is not limited to as such.

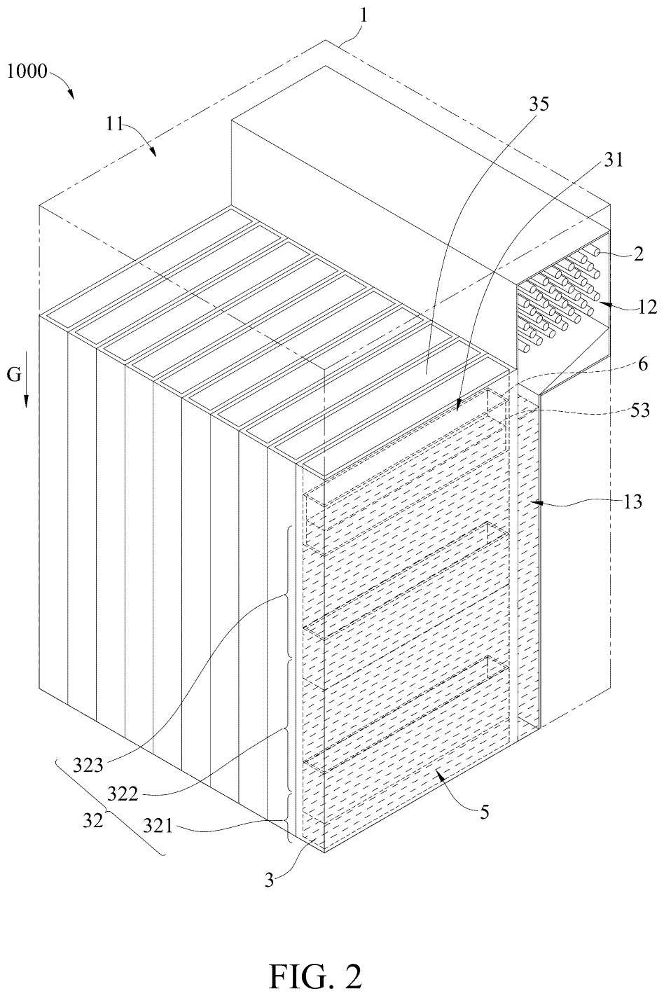

In one embodiment, as shown in FIG. 2, suction units 6 can be respectively disposed on at least one inner sidewall of the tank body 3 between the stratified sections 321, 322, and 323. For example, one suction unit 6 is provided between the stratified sections 321 and 322, and another suction unit 6 is provided between the stratified sections 322 and 323, and the present disclosure is not limited to as such. The purpose of arranging the suction units 6 at the junctions of the stratified sections 321, 322, and 323 is to balance the stratified sections 321, 322, and 323 with large temperature differences so that the temperature distribution of the liquefied heat dissipation medium 52 in the tank body 3 is uniform.

In one embodiment, as shown in FIG. 3, at least one suction unit 6 can also be disposed on the heating unit 4. For example, the suction unit 6 is arranged in an area on the heating unit 4 except for the central processors, graphics chips, other types of chips, or other heat sources that generate heat energy, or the suction unit 6 is arranged in a component space with small heating power. Because these areas or component spaces with small heating power do not require too much liquefied heat dissipation medium 52 to help with cooling, and the suction unit 6 can also guide the liquefied heat dissipation medium 52 of different temperatures to increase the flow of liquid, so that the temperature distribution of the liquefied heat dissipation medium 52 in the tank body 3 is uniform. At the same time, the arrangement of the suction unit 6 can reduce the usage of the heat dissipation medium 5 equivalent to the entire volume of the suction unit 6.

In summary, by arranging a suction unit in the immersion cooling system of the present disclosure, the liquefied heat dissipation medium in the liquid storage space can be guided to the vapor space. Compared with the prior art where only the liquid surface area of the liquefied heat dissipation medium contacts the vapor space, the present disclosure also has an additional liquefied heat dissipation medium located in the suction unit of the vapor space that can contact the vapor space. Therefore, the present disclosure effectively increases the contact area between the liquefied heat dissipation medium and the vapor space, thereby improving the heat exchange efficiency and heat exchange speed. Furthermore, the present disclosure can also have the effects of reducing the usage of heat dissipation medium, uniform temperature distribution of the heat dissipation medium, and no additional power consumption of the flow guiding mechanism.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An immersion cooling system, comprising:
a box body having a first accommodating space;
a plurality of tank bodies arranged in the first accommodating space, wherein each of the plurality of tank bodies contains a heat dissipation medium, and is defined with a vapor space and a liquid storage space connected to the vapor space, wherein a liquefied heat dissipation medium is accommodated in the liquid storage space, and a gasified heat dissipation medium is accommodated in the vapor space; and
at least one suction unit disposed on at least one inner sidewall of each of the tank bodies between the vapor space and the liquid storage space, and configured for attracting the liquefied heat dissipation medium in the liquid storage space and guiding the liquefied heat dissipation medium to the vapor space, so as to increase a contact area between the liquefied heat dissipation medium and the vapor space.

2. The immersion cooling system of claim 1, wherein the suction unit is polyvinyl alcohol foam.

3. The immersion cooling system of claim 2, wherein a porosity of the polyvinyl alcohol foam is between 89% and 95%.

4. The immersion cooling system of claim 2, wherein a pore size of the polyvinyl alcohol foam is between 380 μm and 1100 μm.

5. The immersion cooling system of claim 1, wherein a proportion of the suction unit located in the vapor space and the liquid storage space is 50% each.

6. The immersion cooling system of claim 1, wherein the liquefied heat dissipation medium in the liquid storage space is defined with a plurality of stratified sections along a direction of gravity, and temperatures of the heat dissipation medium in the plurality of stratified sections are different from each other.

7. The immersion cooling system of claim 6, wherein the suction unit is further disposed on the at least one inner sidewall of each of the tank bodies between each of the plurality of stratified sections.

8. The immersion cooling system of claim 1, wherein each of the plurality of tank bodies is provided with a heating unit, and the heating unit is immersed in the liquefied heat dissipation medium in the liquid storage space.

9. The immersion cooling system of claim 8, wherein the suction unit is further disposed on the heating unit.

10. The immersion cooling system of claim 1, wherein the vapor space and the liquid storage space are arranged up and down along a direction of gravity, and the vapor space and the liquid storage space are not connected to the first accommodating space.

11. The immersion cooling system of claim 1, wherein the plurality of tank bodies are arranged side by side in the first accommodating space in a direction perpendicular to a direction of gravity.

12. The immersion cooling system of claim 1, wherein the box body further has a second accommodating space and a water collecting tank connected to the second accommodating space, and the second accommodating space and the water collecting tank are arranged up and down along a direction of gravity.

13. The immersion cooling system of claim 12, further comprising a condensing unit disposed in the second accommodating space, wherein the heat dissipation medium gasifies after absorbing thermal energy, and the gasified heat dissipation medium is introduced into the second accommodating space, so that the gasified heat dissipation medium is condensed and liquefied through heat exchange by the condensing unit, and the liquefied heat dissipation medium is introduced into the water collecting tank and then returned to each of the tank bodies.
